(19) United States
(12) Patent Application Publication
(10) Pub. No.: US 2008/0149322 A1
(43) Pub. Date: Jun. 26, 2008

(54) Metal Coated Graphite Sheet

(75) Inventors: Oswin Ottinger, Meitingen (DE); Martin Christ, Augsburg (DE); Ludger Fischer, Wachtberg-Berkum (DE)

Correspondence Address: LERNER GREENBERG STEMER LLP, P O BOX 2480, HOLLYWOOD, FL, 33022-2480, US

(73) Assignee: SGL CARBON AKTIENGESELLSCHAFT, Wiesbaden (DE)

(21) Appl. No.: 11/962,440

(22) Filed: Dec. 21, 2007

Related U.S. Application Data
(63) Continuation of application No. PCT/EP2006/004601, filed on May 16, 2006.

(30) Foreign Application Priority Data
Jun. 21, 2005 (EP) EP 05 013 340.4

(51) Int. Cl. B32B 15/00; C23C 16/00; A47J 36/02; F28F 7/00

(52) U.S. Cl. 165/185; 428/336; 427/250; 228/101

(57) ABSTRACT

Graphite films are provided with a metal coating of at most 100 nm thick and are produced, for example by a continuous vapor deposition process on graphite film. In spite of the small thickness of the metal layer, the graphite films can be connected to one another or to other components of metal or metal-coated materials by soldering. Furthermore, the thin metal coating protects the surface of the graphite film against particles breaking out or peeling or flaking off.

### CROSS-REFERENCE TO RELATED APPLICATIONS

This is a continuing application, under 35 U.S.C. § 120, of copending international application No. PCT/EP2006/004601, filed May 16, 2006, which designated the United States; this application also claims the priority, under 35 U.S.C. § 119, of European patent application No. EP 050 13 340.4, filed Jun. 21, 2005; the prior applications are herewith incorporated by reference in their entirety.

### BACKGROUND OF THE INVENTION

### Field of the Invention

The present invention relates to graphite sheets having a metal coating which has a thickness of not more than 100 nm and also their production and use.

Graphite sheet is produced by compaction and pressing of expanded graphite. Expanded graphite is formed when graphite intercalation compounds or graphite salts, e.g. graphite hydrogensulfate or graphite nitrate, are heated suddenly. The volume of the graphite particle is in this way increased by a factor of from 200 to 400 and the bulk density drops to from 2 to 20 g/l. The expanded graphite obtained in this way contains worm-shaped or accordion-shaped, bulky aggregates. If these particles are compacted under pressure, they interlock and intermesh with one another. Owing to this effect, self-supporting sheet-like structures, e.g. sheets or plates, can be produced without the addition of a binder. Graphite sheet has a high electrical and thermal conductivity in the plane, i.e. perpendicular to the pressing direction, and can be matched readily to adjacent surfaces.

For particular applications, it is necessary to provide graphite sheet with a coating of metal on all or part of at least one surface. This coating can fulfill various functions such as mechanical reinforcement, increasing the thermal and electrical conductivity and corrosion protection. In addition, a metallic surface is required particularly when the components made of graphite sheet is to be joined by soldering or welding to other, in particular metallic, components or to other components made of expanded graphite.

U.S. Pat. No. 5,100,737 discloses flexible layer composites containing at least one layer of graphite sheet having a metal layer, for example of copper or nickel, on at least one of its surfaces. The thickness of the graphite sheet is from 0.1 to 10 mm, and that of the metal layer is from 1 to 200 μm, preferably from 3 to 50 μm. The layer composites are employed in electrical shielding, seals or as heat sinks. If appropriate, additional bonding layers are provided on the graphite or/and metal layers in order to join a plurality of such layer composites to one another. The bonding layer can be in the form of a thin metal layer (thickness from 1 to 5 μm) or a layer of adhesive.

The metal layers are preferably produced by chemical (i.e. without electric current by use of a reducing agent) or electrolytic deposition. Although other metal coating processes such as spraying with molten metal, thermal spraying, vacuum deposition techniques or CVD are not ruled out in principle, these methods are less preferred because of their lack of suitability for continuous operation. In addition, the difficulties of achieving thin layers by these techniques may be pointed out.

Metal-coated graphite sheets are likewise known from German patent DE 28 17 371 C2 corresponding to U.S. Pat. No. 4,314,172. Stack arrangements of such metal-coated graphite sheets are used as friction bodies in contact brushes of electric machines. The application of the layer can be carried out by the known thin film processes such as electroplating, chemical electroless plating, plasma or ion plating, sputtering or vapor deposition. The vapor deposition technique is preferred since it gives particularly good adhesion of the metal to the graphite sheet. In any case, heating of the graphite sheet to more than 100° C. during coating is to be avoided because the graphite sheet otherwise degasses too strongly and the adhesion of the metal is reduced as a result. The thickness of the applied layers is in the range from 0.1 to 500 μm, preferably from 1 to 50 μm.

### SUMMARY OF THE INVENTION

It is accordingly an object of the invention to provide a metal-coated graphite sheet that overcomes the above-mentioned disadvantages of the prior art devices and methods of this general type.

With the foregoing and other objects in view there is provided, in accordance with the invention, a graphite sheet. The graphite sheet contains a graphite sheet body having at least one surface, and a metal coating disposed on the at least one surface. The metal coating has a thickness of not more than 100 nm.

The present invention provides graphite sheets having a metal coating on at least one side, wherein the metal layer has a thickness of not more than 100 nm. In particular, the invention also provides sheet-like, strip-shaped or similar semifinished parts containing graphite sheet, wherein at least one of the flat sides at least one of the edges of the semifinished part has a metal coating having a thickness of not more than 100 nm. The graphite sheets which have been coated according to the invention have a number of advantageous properties. Thus, it has surprisingly been found that, despite the only small thickness of the metal layer, the graphite sheets of the invention can be joined without difficulties to other components made of metal or metal-coated graphite by soldering. In addition, the thin metal coating provides excellent protection for the surface of the graphite sheet and, if appropriate, also the edges of a semifinished part containing graphite sheet against breaking-out, flaking or splitting-off of graphite particles.

A further object of the invention is to provide a process for producing metal coatings whose thickness does not exceed 100 nm on graphite sheet.

The invention further relates to combinations of such coated graphite sheets and their use.

In accordance with an additional feature of the invention, the metal coating is formed from aluminum, copper, nickel, silver, gold and/or platinum.

In accordance with an added feature of the invention, the graphite sheet body is impregnated with a resin.

In accordance with a further feature of the invention, only selected regions of the surface of the graphite sheet body are coated with the metal coating.

In accordance with another feature of the invention, there is further provided a layer of adhesive having a thickness of up to 10 μm and is covered with a film which can be pulled off and is disposed on the metal coating or the surface which has not been coated with the metal coating.

With the foregoing and other objects in view there is provided, in accordance with the invention, a laminate. The laminate contains two graphite sheets each having a side and a metal coating disposed on the side. The metal coating has a thickness of not more than 100 nm. The two graphite sheets are disposed such that the sides with the metal coating face outward so that both outer sides of the laminate have the metal coating.

With the foregoing and other objects in view there is further provided, in accordance with the invention, a semi-finished part having a sheet shape or a strip shape. The semi-finish part contains a graphite sheet having at least one flat side, at least one edge, and a metal coating having a thickness of not more than 100 nm disposed on the flat side and/or the edge.

With the foregoing and other objects in view there is additionally provided, in accordance with the invention, a process of using graphite sheets. The process includes providing a graphite sheet having a metal coating on at least one surface, the metal coating has a thickness of not more than 100 nm; and disposing the graphite sheet in an electronic instrument for performing at least one of heat transfer, heat removal and heat distribution in the electronic instrument. Optionally, the laminate or the semi-finished part could be used in the electronic instrument.

With the foregoing and other objects in view there is provided, in accordance with the invention, a process of using graphite sheets. The process includes providing a graphite sheet having a metal coating on at least one surface, the metal coating having a thickness of not more than 100 nm; and using the graphite sheet for producing heat exchangers, cooling bodies, heat spreaders and bipolar cooling plates for fuel cell stacks. Optionally, the laminate or the semi-finished part could be used instead of the graphite sheet.

With the foregoing and other objects in view there is further provided, in accordance with the invention, a method of joining components formed of a metal-coated graphite sheet. The method includes providing the metal-coated graphite sheet to have a metal coating with a thickness of not more than 100 nm; and joining the components formed of the metal-coated graphite sheet to each other by soldering or welding. Additionally, the laminates or the semi-finished parts could be joined together by soldering or the welding.

With the foregoing and other objects in view there is provided, in accordance with the invention, a cooling body. The cooling body contains cooling fins formed of graphite sheet, and a base plate being either a metal base plate having recesses or a graphite base plate having recesses. The base plate has walls defining the recesses. The walls are coated with a metal, and the cooling fins are soldered into the recesses. The graphite sheet of the cooling fins has at least one surface region coated with a metal layer, the metal layer has a thickness of not more than 100 nm.

With the foregoing and other objects in view there is provided, in accordance with the invention, a process for producing a one-sided metal coating on graphite sheet. The process includes laminating a plastic film onto one side of a strip of graphite sheet; performing a continuous vapor deposition process of a desired metal to a desired layer thickness on the strip of graphite sheet; and mechanically removing the plastic film laminated from the strip of graphite sheet. Ideally a PET film is used as the plastic film.

In accordance with an added mode of the invention, there is the step of impregnating the strip of graphite sheet with a resin.

In accordance with an added feature of the invention, selected surface regions of the strip of graphite sheet which are to remain uncoated are covered with a mask.

Other features which are considered as characteristic for the invention are set forth in the appended claims.

Although the invention is illustrated and described herein as embodied in a metal-coated graphite sheet, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, side-elevational view, by way of example, illustrating a component in which semifinished parts containing a coated graphite sheet according to the invention are soldered to one another; and

FIG. 2 is a diagrammatic, side-elevational view of a cooling body whose fins contain graphite sheets coated according to the invention in the fastening region.

### DETAILED DESCRIPTION OF THE INVENTION

A metal or metals with which a graphite sheet is coated are selected according to an intended use. Mention may be made by way of example of coatings of aluminum or copper which make it possible to produce soldered connections to other components made of metal or metal-coated materials and also coatings of nickel, silver, gold or platinum metals. The coating can contain a plurality of metals.

If extended areas, for example strips, of graphite sheet are to be coated, they are coated by, for example, continuous vapor deposition of the desired metal. Depending on the plant used, it can be advantageous to reinforce the graphite sheet by lamination on one side with a plastic film, e.g. a PET film, in order to increase the tear strength. Metal is then applied by vapor deposition to the unlaminated surface of the graphite sheet. After vapor deposition is complete, the plastic film is removed again from the uncoated surface of the graphite sheet by mechanical measures.

However, the invention is not tied to this process and other processes including physical vapor deposition (PVD) processes such as coating by sputtering and by ion beam processes are also suitable for producing the coated graphite sheet according to the invention.

Alternatives to these production processes are electrolytic or electroless deposition of the metal layer.

Instead of a continuous strip of graphite sheet, it is also possible to provide individual semifinished parts containing graphite sheet which already have the size and shape required for the intended use, for example square or rectangular pieces of sheet or strips of sheet, with a metal layer having a thickness of not more than 100 nm. For the present purposes, the term semifinished part refers quite generally to structures made of graphite sheet which have, in contrast to continuous strips of sheet, a limited two-dimensional extension, with the shape of this area being able to be selected freely and depending essentially on the intended use.

This procedure has the advantage that not only the flat sides but also the edges of the pieces of sheet can be coated. During handling, processing, installation, etc, the edges, in particular, of the sheet-like, strip-shaped or similar semifinished parts are subjected to mechanical stresses caused by impact, etc. It is therefore particularly desirable to protect not only the flat sides but also the edges against breaking-out, flaking or splitting-off of graphite particles by use of a suitable coating. This is made possible by the coating according to the present invention. During the vapor deposition process, it may be necessary to vary the positioning or alignment of the vapor source appropriately in order to avoid shadowing effects at the edges of the pieces of sheet.

If desired, particular regions of the surface of the graphite sheet can be masked so that they remain uncoated. In this way, particular structures (patterns) can be formed by coating selected regions on the surface of the graphite sheet.

Lamination of two graphite sheets which have been coated on one side with metal, with the coated surfaces facing outward in each case, makes it possible to produce graphite sheet laminates which are coated with metal on both sides, i.e. on both outer sides.

As an alternative, when vapor deposition units are used which do not place great demands on the tensile strength of the sheet to be coated so that no lamination is necessary, two-sided coating in a single pass is also possible.

The graphite sheets to be coated have a thickness of not more than 1.9 g/cm³, preferably from 0.3 to 1.9 g/cm³ and particularly preferably from 0.3 to 1.3 g/cm³.

If necessary, the graphite sheet can be impregnated with a resin or the like in order to fill and close the pores in the sheet before application of the metal layer. This prevents the metal to be deposited on the sheet from getting into the interior of the sheet.

Impregnation of the sheet is particularly advantageous prior to electrolytic or electroless deposition of metal from an electrolyte bath because the impregnation prevents the penetration of the liquid electrolyte into the pores and thus reduces the subsequent drying requirements for the coated sheet.

The metal-coated graphite sheets of the invention can be utilized, for example, for transfer, removal and distribution of heat, e.g. in electronic instruments.

The use of graphite sheet for heat management in electronic instruments is known, for example, from the U.S. Pat. No. 6,482,520. This document discloses a heat management system having a heat source which is in contact on one of its external surfaces with a graphite sheet serving to conduct away heat, known as a thermal interface. The surface of the graphite sheet facing away from the heat source is optionally in contact with a cooling body. In a further development of this thermal interface described in the U.S. patent publication No. US 2002/0163076, the surface facing away from the heat source and, if appropriate, also the edges of the sheet is/are provided with a protective coating to avoid flaking of graphite sheet. Coatings composed of various plastics are proposed. However, these coatings have only a low thermal conductivity so that the actual function of the thermal interface, namely to conduct away heat, is adversely affected thereby.

In contrast thereto, the metal coatings proposed according to the invention combine the advantage of protection of the surface against flaking of graphite particles with the advantage of thermal conductivity.

The thermal conductivity in the graphite sheet is anisotropic with preferential conduction of heat in the plane of the sheet, while that in metals is isotropic. The heat can thus be distributed over a large area within the graphite sheet because of the preferential lateral spread of heat, while the metal layer which, owing to its isotropy, conducts heat to a high degree even transverse to the plane of the sheet can bring about introduction of heat into the graphite sheet or removal of heat from the same.

The ability to produce soldered and welded connections enables three-dimensional structures to be built up from appropriately shaped sheet-like semifinished parts containing the coated graphite sheets of the invention, if appropriate in combination with components made of other metal-coated materials or of metal. In this way, the coated graphite sheets of the invention can be used, for example, for producing heat exchangers, heat spreaders, cooling bodies or bipolar cooling plates for fuel cell stacks. In these and further conceivable applications, it is possible to utilize not only the advantage of the invention, namely that of making it possible to produce soldered and welded connections, but also the combination according to the invention of lateral conduction of electric current or heat in the graphite sheet and isotropic conduction of electric current or heat in the metal layer.

The semi-finished parts required, for example square or rectangular pieces of sheet or strips of sheet, are cut or stamped out of the coated graphite sheet according to the invention. As an alternative, it is also possible to cut or stamp the desired semi-finished parts out of an untreated strip of sheet and then to coat these. This procedure has the advantage that not only the flat sides but also the edges of the semifinished parts can be provided with the metal coating, so that the semi-finished parts are also protected against breaking-out, flaking or splitting-off of graphite particles in the region of the edges.

Laminates containing metal-coated graphite sheets can also be used as semi-finished parts for the construction of three-dimensional structures.

In applications in which fixing of the metal-coated graphite sheet by soldering or welding is not possible or unsuitable, a thin layer of adhesive can be applied to the metal coating. However, this should be as thin as possible in order not to impair heat transfer to the metal layer. Good results have been achieved using 10 μm thick layers of adhesive.

If the side of the graphite sheet which has not been coated with metal is likewise intended for fixing to another component, this can be achieved in the same way using a thin layer of adhesive.

The adhesive can be applied immediately before use. As an alternative, metal-coated graphite sheets having a layer of adhesive on the metal layer or/and on the surface which has not been coated with metal can be prefabricated and then covered with a plastic release film which is pulled off only immediately before use.

### EXAMPLE 1

### Coating of Graphite Sheet with a Thin Metal Layer

A strip of graphite sheet having a thickness of 0.4 mm and a density of 1.2 g/cm³ was laminated on one side with a PET film having a thickness of 12 μm in order to increase the tensile strength of the graphite sheet. The length of the sheet was about 50 m and its width was about 1 m. The composite of graphite sheet and PET film was coated with aluminum by vapor deposition on the surface not covered by PET film in a continuously operating high-vacuum coating unit. The sheet passed through the coating unit at a velocity of about 5 m/s. To determine the thickness of the aluminum layer, a 30×70 mm² specimen was stamped from the coated composite. The PET film was removed mechanically from the specimen. The aluminum content of the remaining graphite-aluminum composite was determined (260 μg) by atomic emission spectroscopy (ICP-AES). The mass per unit area of the aluminum layer was determined from the area of the specimen and the mass of the aluminum layer as 0.12 g/m². With the aid of the density of aluminum (2.7 g/cm³), the thickness of the vapor-deposited aluminum layer was calculated as about 45 nm.

### EXAMPLE 2

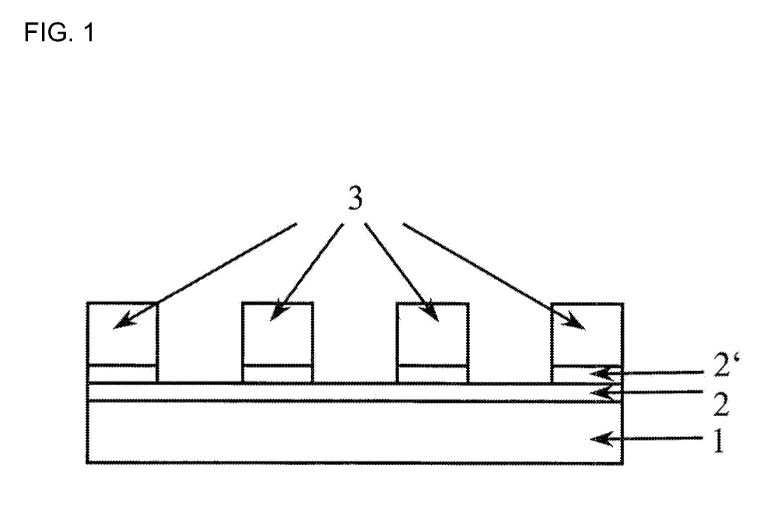

### Production of Soldered Connections Between Graphite Sheets which have been Coated According to the Invention with Aluminum as Best Shown in FIG. 1

Strips 3 of a graphite sheet coated on one side with aluminum 2′ were soldered onto a graphite sheet 1 which had been provided on one side with a thin aluminum coating 2 as described in example 1. For this purpose, commercially available hard soldered powder which is marketed under the name “Amasan” (manufacturer: Armack GmbH—Löttechnik) and is suitable for soldering aluminum and light metal ALU22 was first mixed with water to give a paste. This paste was applied by a brush to the aluminum-coated side of the strips of sheet to be soldered and sprinkled with aluminum powder having a particle size of <100 μm (manufacturer: Schlenk Metallpulver GmbH & Co. KG). The strips of sheet to be soldered were subsequently laid on the aluminum-coated side of the graphite sheet which had been coated by the method described in example 1 and installed in a cold furnace between two plates which served to fix the sheets. The furnace was heated to 650° C. over a period of about 2 hours. This temperature was maintained for 20 minutes, and the specimens were subsequently cooled in the furnace.

The soldered-on strips of sheet adhered very well to the graphite sheet. The PET film laminated onto the graphite sheet to reinforce the latter during vacuum coating of the graphite sheet with aluminum burnt away without leaving a residue during the time in the furnace. Bubble formation caused by outgassing of the sheet was suppressed by the relatively slow heating.

The thickness of the soldered plates increased by about 0.4 mm (solder layer) at the overlapping places. An aluminum layer can no longer be discerned visually at these places.

A channel structure which can be used, inter alia, in heat exchangers can be formed from the resulting structure as shown in FIG. 1 by soldering a further graphite sheet which has been coated according to the invention onto the strips 3 which have been soldered onto the first graphite sheet 1.

### COMPARATIVE EXAMPLE FOR EXAMPLE 2

In a comparative experiment, strips of uncoated graphite sheet were soldered onto uncoated graphite sheet by the above-described method. The adhesion between the soldered parts was significantly lower in this experiment than in the case of the soldered connections between aluminum-coated graphite sheets. Some of the strips became completely detached from the substrate, while others became at least partly detached.

### EXAMPLE 3

### Cooling Body with Soldered-in Fins of Graphite Sheet

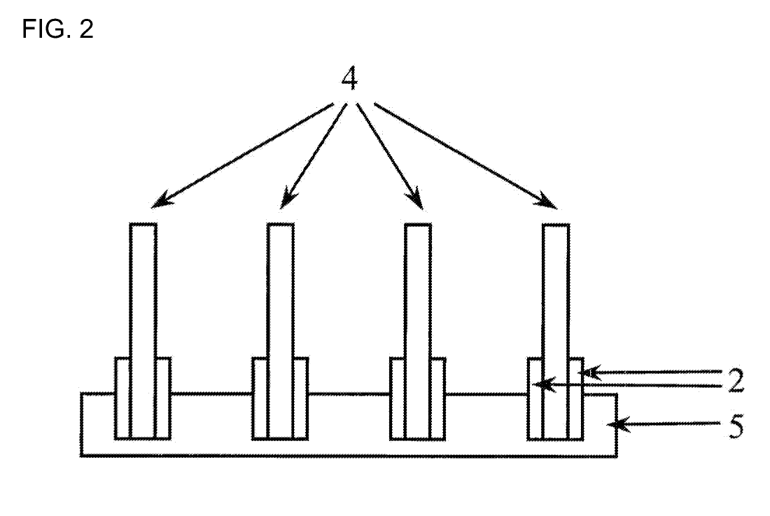

The cooling body as shown in FIG. 2 contains cooling fins 4 of graphite sheet which project from a base plate 5 and remove heat from the latter. Recesses to accommodate the cooling fins 4 are provided on the surface of the base plate 5, which usually is formed of a metal. The cooling fins 4 are soldered into the recesses in the base plate 5. For this purpose, the cooling fins 4 of graphite sheet are provided with a metal coating according to the invention at least in the region of their surface which projects into the recess (the fixing region).

As an alternative, it is possible to use a graphite base plate in which the wall surfaces of the recesses are coated with metal so that fins of graphite sheet which are provided in the fixing region with a metal coating according to the invention can be fixed by soldering into the recesses of the base plate.

1. A graphite sheet, comprising:
graphite sheet body having at least one surface; and
metal coating disposed on said at least one surface, said metal coating having a thickness of not more than 100 nm.

2. The graphite sheet according to claim 1, wherein said metal coating is formed of at least one material selected from the group consisting of metals, aluminum, copper, nickel, silver, gold and platinum.

3. The graphite sheet as claimed in claim 1, wherein said graphite sheet body is impregnated with a resin.

4. The graphite sheet according to claim 1, wherein only selected regions of said surface of said graphite sheet body are coated with said metal coating.

5. The graphite sheet according to claim 4, further comprising a layer of adhesive having a thickness of up to 10 μm and is covered with a film which can be pulled off is disposed on at least one of said metal coating and said surface which has not been coated with said metal coating.

6. A laminate, comprising:
two graphite sheets each having a side and a metal coating disposed on said side, said metal coating having a thickness of not more than 100 nm, said two graphite sheets disposed such that said sides with said metal coating face outward so that both outer sides of the laminate have said metal coating.

7. A semi-finished part having a shape selected from the group consisting of a sheet shape and a strip shape, the semi-finish part comprising:
a graphite sheet having at least one flat side, at least one edge, and a metal coating having a thickness of not more than 100 nm disposed on at least one of said flat side and said edge.

8. A process of using graphite sheets, which comprises the steps of:
providing a graphite sheet having a metal coating on at least one surface, the metal coating having a thickness of not more than 100 nm; and
disposing the graphite sheet in an electronic instrument for performing at least one of heat transfer, heat removal and heat distribution in the electronic instrument.

9. A process of using graphite sheets, which comprises the steps of:
providing a graphite sheet having a metal coating on at least one surface, the metal coating having a thickness of not more than 100 nm; and
using the graphite sheet for producing a product selected from the group consisting of heat exchangers, cooling bodies, heat spreaders and bipolar cooling plates for fuel cell stacks.

10. A method of joining components formed of a metal-coated graphite sheet, which comprises the step of:
providing the metal-coated graphite sheet to have a metal coating with a thickness of not more than 100 nm; and
joining the components formed of the metal-coated graphite sheet to each other by one of soldering and welding.

11. A cooling body, comprising:
cooling fins formed of graphite sheet;
a base plate selected from the group consisting of a metal base plate having recesses formed therein and a graphite base plate having recesses formed therein, said base plate having walls defining said recesses coated with a metal, and said cooling fins being soldered into said recesses; and
said graphite sheet of said cooling fins having at least one surface region coated with a metal layer, said metal layer having a thickness of not more than 100 nm.

12. A process for producing a one-sided metal coating on graphite sheet, which comprises the steps of:
laminating a plastic film onto one side of a strip of graphite sheet;
performing a continuous vapor deposition process of a desired metal to a desired layer thickness on the strip of graphite sheet; and
mechanically removing the plastic film laminated from the strip of graphite sheet.

13. The process according to claim 12, which further comprises laminating the strip of graphite sheet with a PET film as the plastic film.

14. The process according to claim 12, which further comprises impregnating the strip of graphite sheet with a resin.

15. The process according to claim 12, wherein selected surface regions of the strip of graphite sheet which are to remain uncoated are covered with a mask.

16. A process of using graphite sheets, which comprises the steps of:
providing a laminate formed of two graphite sheets each having a side and a metal coating disposed on the side, the metal coating having a thickness of not more than 100 nm, the two graphite sheets disposed such that the sides with the metal coating face outward so that both outer sides of the laminate have the metal coating; and
disposing the laminate in an electronic instrument for performing at least one of heat transfer, heat removal and heat distribution in the electronic instrument.

17. A process of using graphite sheets, which comprises the steps of:
providing a laminate formed of two graphite sheets each having a side and a metal coating disposed on the side, the coating having a thickness of not more than 100 nm, the two graphite sheets disposed such that the sides with the metal coating face outward so that both outer sides of the laminate have the metal coating; and
using the graphite sheets for producing a product selected from the group consisting of heat exchangers, cooling bodies, heat spreaders and bipolar cooling plates for fuel cell stacks.

18. A method of joining components formed from laminates, which comprises the steps of:
forming each of the laminates by providing two graphite sheets each having a side and a metal coating disposed on the side, the coating having a thickness of not more than 100 nm, the two graphite sheets disposed such that the sides with the metal coating face outward so that both outer sides of a laminate have the metal coating; and
joining the components formed of the laminates to each other by one of soldering and welding.
